(19) United States
(12) Patent Application Publication
(10) Pub. No.: US 2017/0040333 A1
(43) Pub. Date: Feb. 9, 2017

(54) Contact Plug Constrained By Dielectric Portions

(71) Applicant: SanDisk Technologies, Inc., Plano, TX (US)

(72) Inventors: Keita Kumamoto, Yokkaichi (JP); Yuji Takahashi, Yokkaichi (JP); Hidetoshi Nakamoto, Yokkaichi (JP); Tomoyasu Kakegawa, Yokkaichi (JP); Shunsuke Akimoto, Yokkaichi (JP); Hidehito Koseki, Yokkaichi (JP); Takuya Futase, Yokkaichi (JP)

(21) Appl. No.: 14/817,093

(22) Filed: Aug. 3, 2015

(51) Int. Cl. H01L 27/115; H01L 21/02; H01L 21/306; H01L 29/06; H01L 29/40

(52) U.S. Cl. CPC H01L 27/11524; H01L 29/0649; H01L 29/401; H01L 21/30608; H01L 21/0217; H01L 21/02164

(57) ABSTRACT

A NAND flash memory includes active areas separated by STI structures in a substrate with a layer of a first dielectric over the substrate. Portions of a second dielectric extend over the STI structures and another layer of the first dielectric extends over both the layer and portions, with contact holes extending through the dielectric layers at locations over the active areas in the semiconductor substrate.

### BACKGROUND

This application relates generally to non-volatile semiconductor memories of the flash memory type, their formation, structure and use.

There are many commercially successful non-volatile memory products being used today, particularly in the form of small form factor cards, USB drives, embedded memory, and Solid State Drives (SSDs) which use an array of flash EEPROM cells. An example of a flash memory system is shown in FIG. 1, in which a memory cell array 1 is formed on a memory chip 12, along with various peripheral circuits such as column control circuits 2, row control circuits 3, data input/output circuits 6, etc.

One popular flash EEPROM architecture utilizes a NAND array, wherein a large number of strings of memory cells are connected through one or more select transistors between individual bit lines and a reference potential. A portion of such an array is shown in plan view in FIG. 2A. Although four floating gate memory cells are shown in each string, the individual strings typically include 16, 32 or more memory cell charge storage elements, such as floating gates, in a column. Control gate (word) lines labeled WL0-WL3 and string selection lines, Drain Select Line, “DSL” and Source Select Line “SSL” extend across multiple strings over rows of floating gates. An individual cell within a column is read and verified during programming by causing the remaining cells in the string to be turned on hard by placing a relatively high voltage on their respective word lines and by placing a relatively lower voltage on the one selected word line so that the current flowing through each string is primarily dependent only upon the level of charge stored in the addressed cell below the selected word line. That current typically is sensed for a large number of strings in parallel, thereby to read charge level states along a row of floating gates in parallel.

The top and bottom of the string connect to the bit line and a common source line respectively through select transistors (source select transistor and drain select transistor). Select transistors do not contain floating gates and are used to connect NAND strings to control circuits when they are to be accessed, and to isolate them when they are not being accessed.

NAND strings are generally connected by conductive lines in order to form arrays that may contain many NAND strings. At either end of a NAND string a contact area may be formed by appropriately doping a portion of the substrate. This allows connection of the NAND string as part of the array. Metal contacts may be formed over contact areas to connect the contact areas (and thereby connect NAND strings) to conductive metal lines that extend over the memory array (e.g. bit lines). FIG. 2A shows bit line contacts BL0-BL4 and common source line contacts at either end of NAND strings. Contacts to contact areas may be formed by etching contact holes through a dielectric layer and then filling the holes with metal. As dimensions of devices in the memory array get smaller, contact holes get smaller and control of contact hole formation may become more difficult.

Thus, there is a need for a memory chip manufacturing process that forms contact holes for contacting NAND strings with very small dimensions, and that allows good control of contact hole formation.

### SUMMARY

In some integrated circuits, such as NAND flash memories, misalignment of contact plugs with active areas in a substrate may have negative consequences including current leakage and open connections. Contact hole bending may also result in such problems. Portions of dielectric material located over STI structures may block contact holes that extend towards neighboring active areas and may constrain them to an intended active area. Such portions of dielectric material may be formed of different material to the surrounding material so that they are not significantly affected by contact holes formed using selective etching. For example, silicon nitride portions in silicon oxide allow selective etching of silicon oxide that is constrained by the silicon nitride portions. Portions of silicon nitride may be self-aligned with a pattern of STI structures and active areas by recessing STI structures, depositing a liner layer (e.g. silicon oxide), and subsequently forming silicon nitride portions in the lined recesses. Alternatively, portions of silicon nitride may be formed in holes in a relatively thin lower silicon oxide layer, with holes aligned with active areas and subsequently covered by a thicker upper silicon oxide layer.

An example of a NAND flash memory includes: a plurality of active areas in a semiconductor substrate; a plurality of shallow trench isolation structures in the semiconductor substrate between the plurality of active areas; a first dielectric layer formed of a first material extending over the substrate; a plurality of portions of a second material extending over the plurality of shallow trench isolation structures; a second dielectric layer formed of the first material extending over the first dielectric layer and over the plurality of portions; and a plurality of contact holes extending through the first and second dielectric layers at locations over the plurality of active areas in the semiconductor substrate.

An individual contact hole may be constrained by a portion of the second material where the contact hole extends in a direction that is not perpendicular to a primary surface of the semiconductor substrate, or where the contact hole is misaligned with a corresponding active area. A plurality of metal contacts may be formed in the plurality of contact holes. The plurality of metal contacts may form electrical connections with bit lines that extend over the semiconductor substrate. The plurality of shallow trench isolation structures may have upper surfaces that are lower than upper surfaces of the plurality of active areas with trenches over shallow trench isolation structures lined by the first dielectric layer and the plurality of portions of the second material may fill central portions of the trenches. The plurality of portions of the second material may have upper surfaces that are higher than the upper surfaces of the plurality of active areas and may have lower surfaces that are lower than the upper surfaces of the plurality of active areas. The plurality of shallow trench isolation structures may have upper surfaces that are approximately level with upper surfaces of the plurality of active areas and the plurality of portions of the second material may have lower surfaces that are substantially level with the upper surfaces of the plurality of shallow trench isolation structures and the plurality of active areas. The plurality of portions of the second material may be located over peripheral areas of shallow trench isolation structures. The plurality of portions of the second material may extend partially over boundaries between shallow trench isolation structures and active areas to overlie peripheral areas of active areas. The plurality of portions of the second material may extend in a vertical direction and may be connected to a layer of the second material. The first material may be silicon oxide, and the second material may be silicon nitride. An individual active area may have a lateral dimension of less than thirty nanometers (30 nm) and the contact holes may have a vertical dimension of greater than four hundred nanometers (400 nm).

An example of a method of forming contact holes through a dielectric layer includes: forming alternating active areas and shallow trench isolation structures in a substrate, the shallow trench isolation structures having upper surfaces that are lower than upper surfaces of the active areas; depositing a first dielectric layer over the substrate, the first dielectric layer formed of a first dielectric material; subsequently depositing a second dielectric material over the first dielectric layer, subsequently removing excess second dielectric material to leave portions of the second dielectric material over the shallow trench isolation structures; subsequently depositing a second dielectric layer, the second dielectric layer formed of the first dielectric material; subsequently forming an etch mask to define contact hole openings in the first dielectric material at locations over active areas; and subsequently etching a plurality of contact holes in the first and second dielectric layers, the plurality of contact holes etched by a process that etches the first dielectric material at a first etch rate and etches the second dielectric material at a second etch rate, the first etch rate being significantly higher than the second etch rate.

Forming the alternating active areas and shallow trench isolation structures may include lowering the upper surfaces of the shallow trench isolation structures by etching. The first material may be silicon oxide, the second material may be silicon nitride, and the etching may be anisotropic etching with a high silicon oxide etch rate. Removing excess second dielectric material may include planarizing to remove all of the second dielectric material that is not within trenches formed between active areas lined by the first dielectric layer. The method may also include: forming one or more additional dielectric layers over the second dielectric layer, the etch mask subsequently formed over the one or more additional dielectric layers, and the plurality of contact holes etched through the one or more additional dielectric layers.

An example of a method of forming contact holes through a dielectric layer includes: forming alternating active areas and shallow trench isolation structures in a substrate; depositing a first dielectric layer over the substrate, the first dielectric layer formed of a first dielectric material; subsequently forming a plurality of openings through the first dielectric layer over the active areas thereby exposing the active areas; subsequently depositing a second dielectric material over the first dielectric layer and within the openings; subsequently depositing a second dielectric layer, the second dielectric layer formed of the first dielectric material; subsequently forming an etch mask to define contact hole openings in the second dielectric layer at locations over active areas; and subsequently etching a plurality of contact holes in the first and second dielectric layers, the plurality of contact holes etched by a process that etches the first dielectric material at a first etch rate and etches the second dielectric material at a second etch rate, the first etch rate being significantly higher than the second etch rate.

Upper surfaces of active areas and shallow trench isolation structures may be coplanar, the first dielectric layer may be substantially planar, and the second dielectric may be deposited along inner walls of the openings and along an upper surface of the first dielectric layer. The method may also include: removing the second dielectric along the upper surface of the first dielectric layer and along the active area prior to deposition of the second dielectric layer. The second dielectric material may form an etch-stop layer, and the etching may include a first etch stage that etches through the first material and a second etch stage that etches through the second dielectric material to expose the active area.

Various aspects, advantages, features and embodiments are included in the following description of examples, which description should be taken in conjunction with the accompanying drawings.

### BRIEF DESCRIPTION OF THE DRAWINGS

FIG. 1 is a block diagram of a prior art memory system.

FIG. 2A is a plan view of a prior art NAND array.

FIG. 2B shows a cross section of the NAND array of FIG. 2A.

FIG. 2C shows another cross section of the NAND array of FIG. 2A.

FIG. 3 illustrates a prior art contact plug with misalignment.

FIG. 4 illustrates a prior art contact hole with contact hole bending.

FIG. 5 illustrates a structure that reduces effects of misalignment and/or hole bending.

FIGS. 6A-F illustrate process steps for forming a structure as shown in FIG. 5.

FIG. 7 illustrates an example of process steps for forming a NAND memory.

FIGS. 8A-F illustrate another example of a process for forming a NAND memory.

FIGS. 9A-D illustrate an alternative process and structure.

FIG. 10 illustrates an alternative with silicon nitride overlying an active area.

FIG. 11 shows process steps used to form a NAND flash memory.

### DETAILED DESCRIPTION OF EXEMPLARY EMBODIMENTS

### Memory System

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure.

In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

In other embodiments, types of memory other than the two dimensional and three dimensional exemplary structures described here may be used.

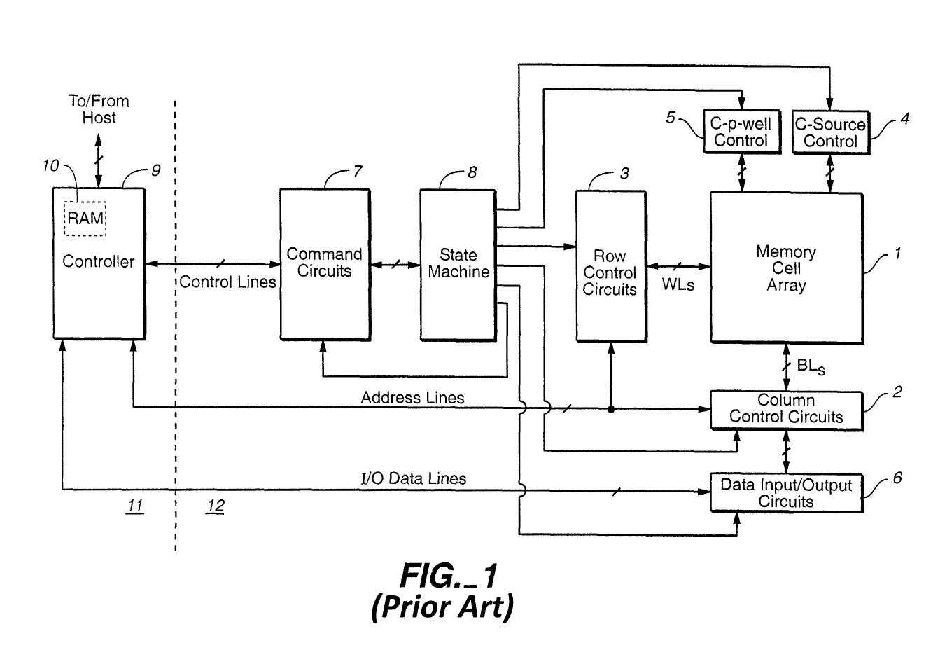

An example of a prior art memory system, which may be modified to include various structures described here, is illustrated by the block diagram of FIG. 1. A planar memory cell array 1 including a plurality of memory cells is controlled by a column control circuit 2, a row control circuit 3, a c-source control circuit 4 and a c-p-well control circuit 5. The memory cell array 1 is, in this example, of the NAND type similar to that described above in the Background and in references incorporated therein by reference. A control circuit 2 is connected to bit lines (BL) of the memory cell array 1 for reading data stored in the memory cells, for determining a state of the memory cells during a program operation, and for controlling potential levels of the bit lines (BL) to promote the programming or to inhibit the programming. The row control circuit 3 is connected to word lines (WL) to select one of the word lines (WL), to apply read voltages, to apply program voltages combined with the bit line potential levels controlled by the column control circuit 2, and to apply an erase voltage coupled with a voltage of a p-type region on which the memory cells are formed. The c-source control circuit 4 controls a common source line (labeled as “c-source” in FIG. 1) connected to the memory cells (M). The c-p-well control circuit 5 controls the c-p-well voltage.

The data stored in the memory cells are read out by the column control circuit 2 and are output to external I/O lines via an I/O line and a data input/output buffer 6. Program data to be stored in the memory cells are input to the data input/output buffer 6 via the external I/O lines, and transferred to the column control circuit 2. The external I/O lines are connected to a controller 9. The controller 9 includes various types of registers and other memory including a volatile random-access-memory (RAM) 10.

The memory system of FIG. 1 may be embedded as part of the host system, or may be included in a memory card, USB drive, or similar unit that is removably insertible into a mating socket of a host system. Such a card may include the entire memory system, or the controller and memory array, with associated peripheral circuits, may be provided in separate cards. The memory system of FIG. 1 may also be used in a Solid State Drive (SSD) or similar unit that provides mass data storage in a tablet, laptop computer, or similar device. Memory systems may be used with a variety of hosts in a variety of different environments. For example, a host may be a mobile device such as a cell phone, laptop, music player (e.g. MP3 player), Global Positioning System (GPS) device, tablet computer, or the like. Such memory systems may be inactive, without power, for long periods during which they may be subject to various conditions including high temperatures, vibration, electromagnetic fields, etc. Memory systems for such hosts, whether removable or embedded, may be selected for low power consumption, high data retention, and reliability in a wide range of environmental conditions (e.g. a wide temperature range). Other hosts may be stationary. For example, servers used for internet applications may use nonvolatile memory systems for storage of data that is sent and received over the internet. Such systems may remain powered up without interruption for extended periods (e.g. a year or more) and may be frequently accessed throughout such periods. Individual blocks may be frequently written and erased so that endurance may be a major concern.

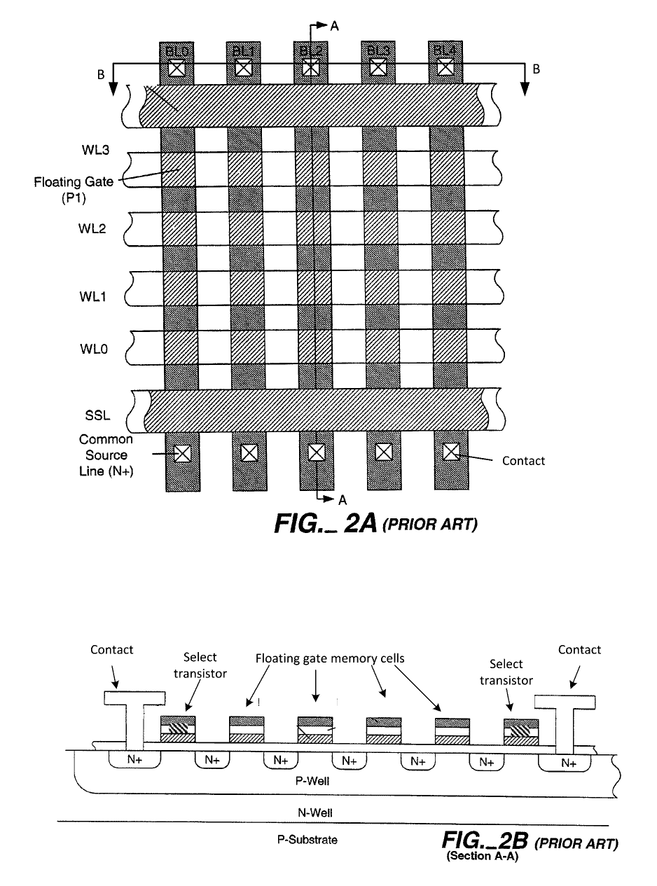

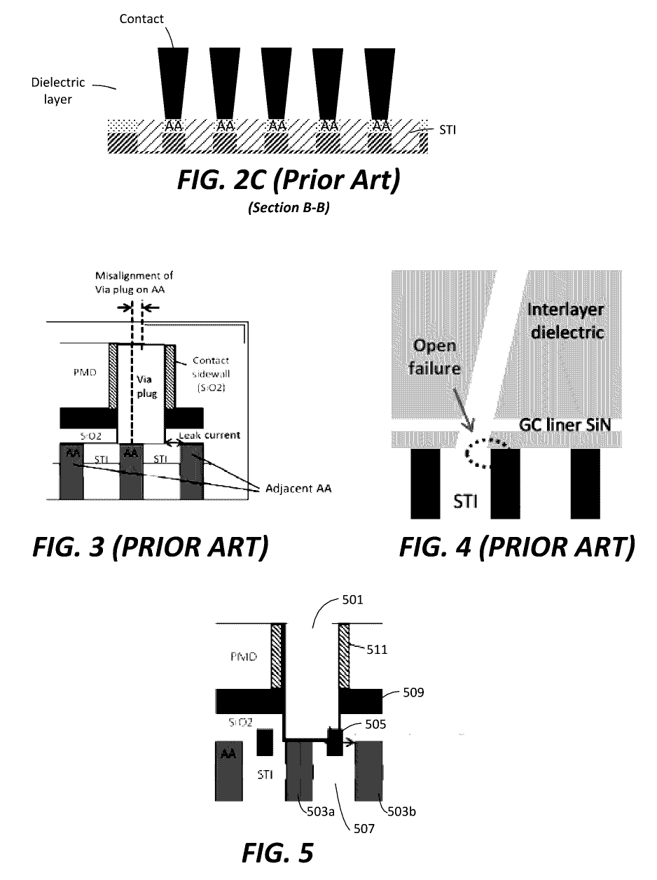

FIGS. 2A-2C show different views of a prior art NAND flash memory. In particular, FIG. 2A shows a plan view of a portion of such a memory array including bit lines and word lines (this is a simplified structure with a small number of word lines and bit lines). FIG. 2B shows a cross section along A-A (along a NAND string) showing individual memory cells that are connected in series. Contacts are formed at either end to connect the NAND strings in the memory array (e.g. connecting to bit lines at one end and to a common source line at the other end). Such a contact may be formed of metal that is deposited into a contact hole that is formed in a dielectric layer. FIG. 2C shows a cross section along B-B of FIG. 2A. This view shows metal contacts extending down through contact holes in a dielectric layer to make contact with active areas (“AA”) in the substrate (i.e. with N+ areas of FIG. 2B). STI regions are located between active areas of different strings to electrically isolate an individual NAND string from its neighbors.

As memory dimensions get smaller, some problems may be encountered when forming contact holes for electrical connection to NAND strings. In general, as such contact holes become narrower, and their cross sectional area (in plan view) becomes smaller, they become harder to control. For example, alignment of very small features may be difficult because tolerance for alignment is generally reduced as feature sizes shrink. FIG. 3 shows an example of misalignment of a contact plug (also referred to as a “via” or “via plug”) with an underlying active area (“AA”). It can be seen that, while the contact plug makes contact with the desired active area it also extends a significant distance over an adjacent STI structure (“STI”) so that a narrow gap separates the contact plug from an adjacent active area. Such a small gap may allow current leakage between the contact plug and an adjacent active area (“Leak current”), which may have a negative impact on memory characteristics. Contact plugs may be made smaller (i.e. their lateral dimensions may be smaller) so that a greater gap between contact plugs and adjacent active areas remains when misalignment occurs. However, such smaller contact plugs may have reduced contact area with corresponding active areas so that contact resistance is increased.

In addition to alignment error, narrow high-aspect ratio contact holes on at least some areas of a substrate such as a silicon wafer may not extend perpendicularly to the substrate surface. Instead, such contact holes may bend to one side, deviating from perpendicular, as they go down through a dielectric layer. This may be related to their location on a substrate or other factors. For example, memory holes in dies near the edge of a substrate may tend to bend significantly because of nonuniform etching conditions. This may become more severe over time as a process kit becomes worn (e.g. contact hole bending may only become significant after a number of substrates have been processed in a given etch chamber and only in certain areas of a substrate surface). Magnetic fields, electric fields, gas flows, temperature profiles, and other process parameters may vary across a wafer and over time. Such variation may provide at least some contact hole bending on at least some dies for at least some period of time. In general, the effects of contact hole bending are worse as contact hole aspect ratios increase (where aspect ratio is the ratio of contact hole height to width). In order to maintain adequate electrical isolation, dielectric layer thicknesses may not be reduced proportionally as lateral dimensions are reduced so that aspect ratios may tend to increase as technology moves to smaller dimensions.

FIG. 4 illustrates how contact hole bending may affect contacts in NAND memories. Contact holes are defined by a pattern of openings in a masking layer that is aligned with active areas that are to be contacted (no misalignment in this example). When contact holes bend to one side as shown, there may be poor contact, or no contact (“Open failure”) with a corresponding active area (“AA”), i.e. contact hole ends on STI structure (“STI”). In some cases bending may cause a contact hole that is intended to contact a particular active area to contact a neighboring active area instead, or to contact both active areas thus shorting neighboring NAND strings. In some cases, there may be contact holes that suffer from both a degree of misalignment and contact hole bending. These and other problems, either individually or in combination, may make contact plug formation difficult particularly when feature sizes are small and aspect ratios are high.

FIG. 5 shows an example of a contact plug 501 that contacts an active area 503a. Contact plug 501 is misaligned with a corresponding active area 503a and has a similar degree of misalignment as shown in the example of FIG. 3. However, in FIG. 5 silicon nitride (SiN) portion 505 is located over the STI structure 507 so that the gap between the contact plug 501 and adjacent active area 503b (gap indicated by arrow) is increased compared with the example of FIG. 3. Thus, the presence of silicon nitride portion 505 constrains the contact plug 501 (by constraining the contact hole in which contact plug 501 is formed) and thereby maintains a gap that ensures little or no current leakage between contact plug 501 and adjacent active area 503b. Portions of silicon nitride, or other suitable material, located over STI structures may provide protection from the impact of misalignment, contact hole bending, and/or other contact hole problems.

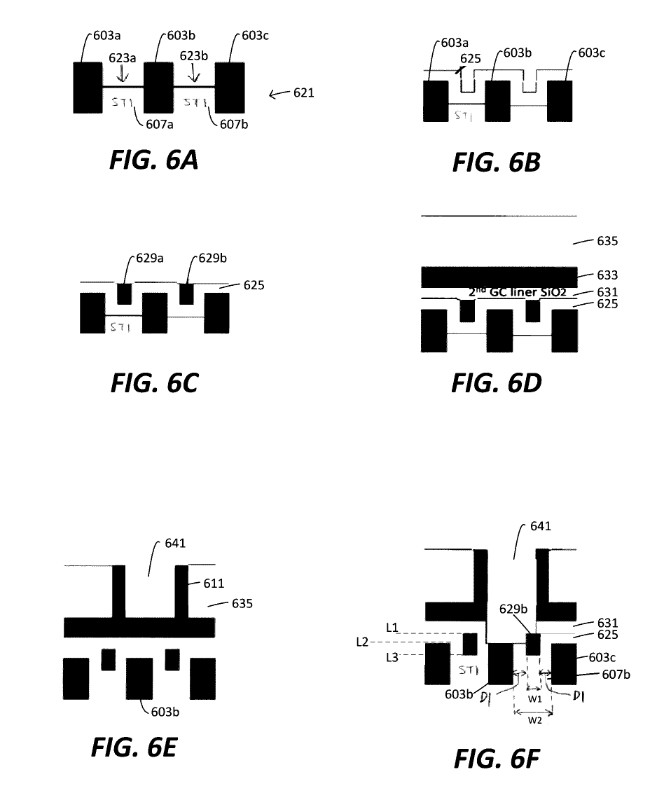

The structure of FIG. 5 and similar structures may be formed by any suitable process. It will be understood that the example of FIG. 5 shows particular layers that may not be present in some examples. For example, a silicon nitride layer 509 and contact sidewall 511 may not be provided in some examples. The structure of FIG. 5, and process used to form it, may be applicable across a range of feature sizes. In one example, a contact plug is approximately nineteen and a quarter nanometers (19.25 nm) apart from an adjacent active area in the designed feature size (without misalignment) and vertical height of approximately five hundred nanometers (500 nm). Misalignment depends on equipment used. For example, misalignment may be in a range up to nineteen nanometers (19 nm) for a particular set of equipment. A distance of at least about ten nanometers (e.g. 9.74 nm) maybe desirable between a contact plug and adjacent active area in order to maintain leakage at acceptable levels. FIGS. 6A-F show an example of a series of process steps that may be used to form a structure like that shown in FIG. 5.

FIG. 6A illustrates an example of a substrate 621 at an intermediate stage of fabrication. FIG. 6A and subsequent figures show a cross section along a plane that is perpendicular to the active areas 603a-c and STI structures 607a-b shown (i.e. cross section is along the word line direction) at a location where contact is to be made to active area 603b. Thus, the view corresponds to a cross section at a location like that illustrated by B-B in FIG. 2A. FIG. 6A illustrates selective etching of STI material to form recesses 623a-b over STI structures 607a-b. Thus, the upper surfaces of STI structures 607a-b are reduced to a level that is lower than the upper surfaces of active areas 603a-c.

FIG. 6B shows the structure of FIG. 6A after subsequent deposition of a first dielectric layer 625 of a first dielectric material, which in this example is silicon oxide (e.g. SiO2). First dielectric layer 625 covers side and bottom surfaces of recesses 623a-b between active areas 603a-c but does not fill these recesses. The thickness of a first dielectric layer may be chosen according to the dimensions of the recess so that a suitable portion of the recess remains unfilled.

FIG. 6C shows the structure of FIG. 6B after deposition of a second dielectric material and subsequent planarization (e.g. etch back or chemical mechanical polishing (CMP)) to leave second dielectric portions 629a-b as shown. Second dielectric portions 629a-b are formed of silicon nitride in this example. Other materials may be used in other examples. The dimensions of dielectric portions 629a-b may be controlled by recess depth, first dielectric layer thickness, and planarization level.

FIG. 6D shows the structure of FIG. 6C after deposition of additional dielectric layers, which in this example include a layer of first dielectric material 631, “2^{nd} GC liner SiO2” (e.g. silicon oxide), a layer of silicon nitride 633, “GC liner SiN”, and a second dielectric layer 635. It will be understood that different dielectric layers may be deposited at this stage depending on process needs.

FIG. 6E illustrates the structure of FIG. 6D after patterning and partial etching of a contact hole 641 through second dielectric layer 635 and formation of a sidewall 611 within contact hole 641 (sidewall formed of silicon oxide). It can be seen that contact hole 641 is misaligned with corresponding underlying active area 603b.

FIG. 6F shows the structure of FIG. 6E after further etching of contact hole 641 down through silicon nitride layer 633, and layers of first dielectric 631, 625, to the upper surface of active area 603b, thereby exposing upper surface of active area 603b. It can be seen that this etch encounters dielectric portion 629b and that etching stops on dielectric portion 629b. A suitable etch chemistry may be chosen so that first dielectric material (of layers 631 and 625) may be selectively removed while dielectric portions 629a-b remain in place. For example, silicon oxide may be selectively removed while silicon nitride remains. Thus, dielectric portion 629b constrains contact hole 641 in the area over the STI structure 607b so that contact hole 641 remains away from neighboring active area 603c.

Dielectric portion 629b can be seen to have a width, W1, that is determined by the width of the STI structure, W2, and the thickness of the first dielectric layer, D1 (W1=W2−2*D1). By choosing a suitable value for D1, width W1 can be chosen to maintain a minimum distance between contact plugs and neighboring active areas that ensures little or no leakage current. The vertical dimensions of dielectric portions such as portion 629b may also be selected according to requirements. Dielectric portions have upper surfaces at level L1, which is higher than upper surfaces of active areas at level L2. Lower surfaces of dielectric portions are lower than L2 at level L3. Level L3 may be established by etching recesses to an appropriate depth. Level L1 may be established by planarizing down to level L1. Contact hole 641 is subsequently filled with metal (and barrier layer(s) as appropriate) so that the resulting contact plug has the dimensions of contact hole.

While the example of FIG. 6F shows misalignment, it will be understood that the structure shown is equally applicable to confining a contact hole that deviates because of hole bending, or because of a combination of misalignment and contact hole bending, or for other reasons.

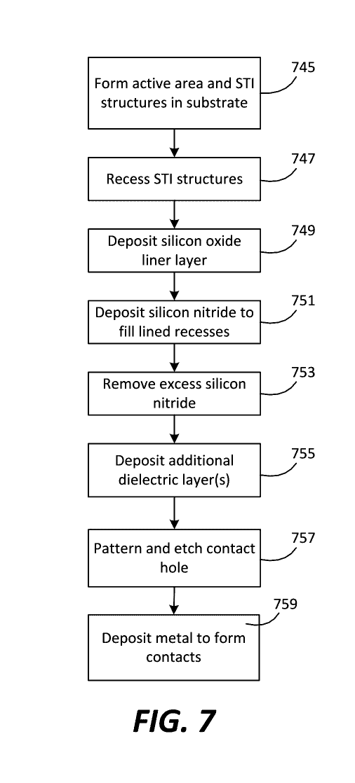

FIG. 7 illustrates process steps used to form a NAND flash memory according to an example. Active areas and STI structures are formed 745 in a substrate. STI structures are then recessed 747 by selectively etching back STI material. A silicon oxide liner layer is then deposited 749 so that it overlies active areas and extends along side and bottom surfaces of recesses. Silicon nitride is deposited 751 to fill the recesses that were lined with the silicon oxide liner layer. Then excess silicon nitride is removed 753, e.g. by etching back or by CMP. Subsequently, one or more dielectric layers are deposited 755 over the structure. Then, patterning and etching of contact holes 757 extends contact holes to expose active areas using an etch that is selective to silicon oxide and does not significantly etch silicon nitride. Thus, if etching of contact holes encounters silicon nitride portions, the etched contact hole is confined so that it does not extend too close to neighboring active areas. The contact holes are then filled by depositing metal 759, and excess metal is removed, to leave contact plugs in contact holes.

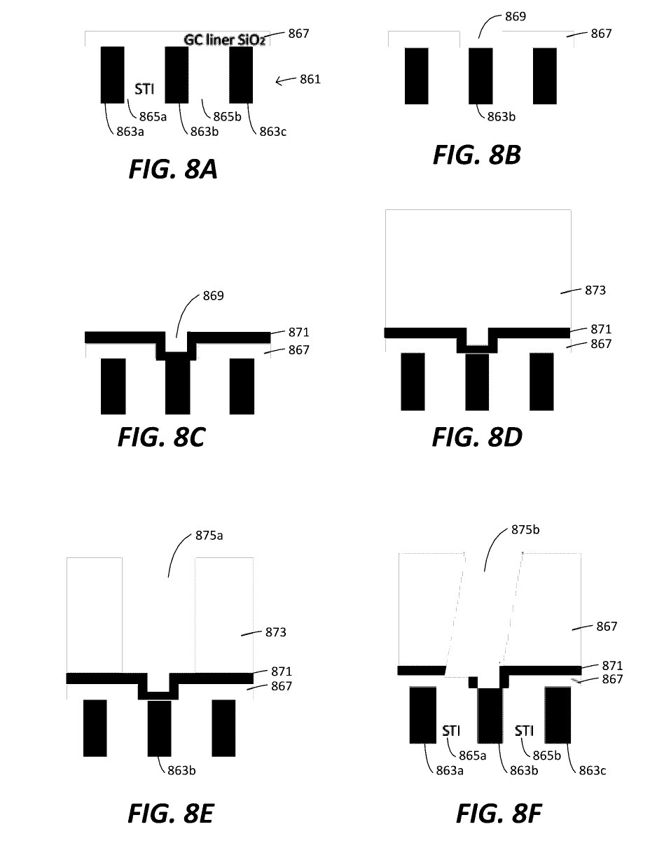

Another example of a process for forming a NAND flash memory is shown in FIGS. 8A-F. In contrast to the example of FIGS. 6A-F, in which portions of silicon nitride were self-aligned with the STI structures and active areas (with no separate patterning steps being used to define the portions), in this example, an additional patterning step is used. Accordingly, this example may be appropriate for addressing contact hole bending.

FIG. 8A shows a silicon substrate 861 at an intermediate stage of fabrication after formation of active areas (“AA”) 863a-c separated by STI structures 865a-b. A first dielectric layer 867, “GC liner SiO2”, extends over the substrate surface including active areas and STI structures. First dielectric layer 867 may be formed of a suitable dielectric, for example silicon oxide. Unlike the previous example, there are no recesses in this example so that upper surfaces of STI structures 865a-b are co-planar with upper surfaces of active areas 863a-c (i.e. STI trenches are filled up to the level of the upper surface of the substrate 861). Thus, first dielectric layer 867 is substantially planar.

FIG. 8B shows the structure of FIG. 8A after formation of an opening 869 through first dielectric layer 867 over active area 863b, thus exposing upper surface of active area 863b. Opening 869 may be formed by patterning (i.e. depositing photoresist and patterning by photolithography) and etching. Thus, the location of opening 869 may be determined by alignment of a mask pattern and may be subject to misalignment. The thickness of first dielectric layer 867 may be chosen so that the effects of contact hole bending are not significant (i.e. first dielectric layer 867 may represent a relatively small fraction of the total dielectric thickness required). For example, where overall dielectric thickness (contact plug height) is about five hundred nanometers (500 nm), a first dielectric layer may be thirty nanometers (30 nm) thick and a subsequent layer, or layers may provide the additional four hundred and seventy nanometers (470 nm) of dielectric. Thus, opening 869 may be considered a low aspect ratio opening.

FIG. 8C shows the structure of FIG. 8B after deposition of a liner dielectric layer 871, which in this case is formed of silicon nitride. Liner dielectric layer 871 extends over first dielectric layer 867 and extends into opening 869, covering side and bottom surfaces of opening 869.

FIG. 8D shows the structure after formation of a second dielectric layer 873. Second dielectric layer 873 may be formed of the same material as first dielectric layer 867, in this example: silicon oxide.

FIG. 8E shows the structure of FIG. 8D after patterning and partial etching of a contact hole 875a. Contact hole 875a extends through second dielectric layer 873, exposing a portion of liner dielectric layer 871, at this stage. Subsequently, a second etch step etches through liner dielectric layer 871 to expose active area 863b. This second etching step may be selective to liner dielectric layer 871 (e.g. selective to silicon nitride) so that it stops on the upper surface of first dielectric layer.

FIG. 8F shows an example of a contact hole 875b with significant contact hole bending at a time after selective etching of liner dielectric layer 871. Contact hole 875b has a relatively high aspect ratio (compared with low aspect ratio opening 869). While the contact hole 875b extends to the surface of active area 863b, over STI structures 865a-b, contact hole 875b does not reach the level of the substrate surface so that some distance is maintained between the contact hole 875b and adjacent active area 863a. Thus, even though contact hole 875b is bent towards neighboring active area 863a, remaining first dielectric layer 871 remains in place over STI structure 865a so that an adequate separation is maintained to prevent significant current leakage when contact hole 875b is filled with metal to form a contact plug.

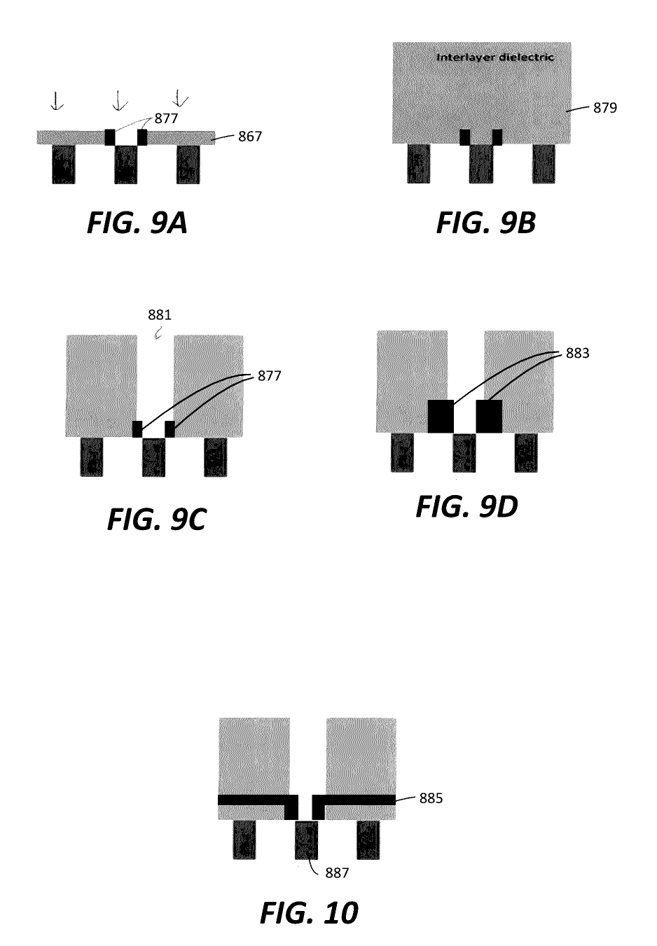

Variations on the above described steps may be carried out in a number of ways. FIGS. 9A-C show an example in which liner dielectric layer 871 (e.g. SiN) is etched back after deposition, prior to deposition of any overlying layer (i.e. between the stages shown by FIGS. 8C and 8D). Thus, the order of steps shown previously is modified. Silicon nitride 877 remains only at the location shown in FIG. 9A after etching back. Silicon nitride 877 may form a ring, collar, or wall around the top surface of an active area where contact is to be made. FIG. 9B shows the structure after subsequent deposition of a second dielectric layer 879. FIG. 9C shows the structure after etching of contact hole 881. Where the contact hole encounters silicon nitride 877 it is confined and thus maintains a larger distance from neighboring active areas. The dimensions of silicon nitride portions 877 may be selected to provide a desired tolerance for misalignment and/or contact hole bending. FIG. 9D shows an example in which silicon nitride portions 883 are larger so that there is increased tolerance for misalignment and/or contact hole bending. Dimensions may be controlled by controlling the thickness of first and second dielectric layers.

Dielectric portions are not limited to overlying STI structures. In some cases, dielectric portions may partially or completely overlie active areas. FIG. 10 shows an example in which a smaller opening is initially formed in a first dielectric layer so that silicon nitride 885 extends partially over upper surface of active area 887.

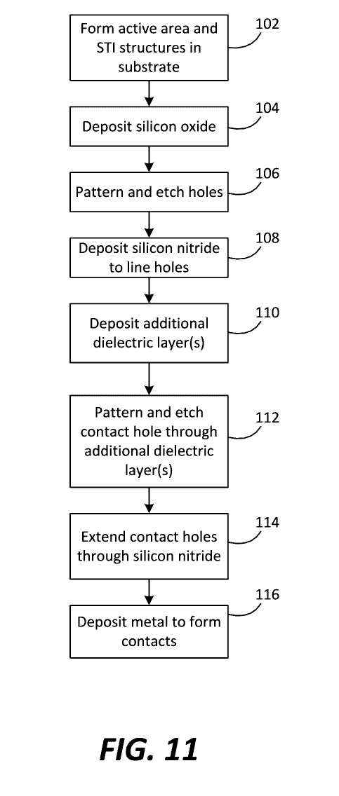

FIG. 11 shows an example of process steps used to form a NAND flash memory. Active areas are formed 102 in a substrate and are separated by STI structures. In this example, upper surfaces of STI structures are at the same level as the upper surface of the substrate. A silicon oxide layer is deposited 104, then patterned and etched 106 so that holes overlie active areas at locations where contact plugs are to be formed. Silicon nitride is deposited 108 to line holes (i.e. silicon nitride extends along side and bottom surfaces of holes). An additional layer or layers are then deposited 110. Contact holes are then partially formed 112 by patterning and etching through the additional layer or layers. The contact holes are then extended 114 through the silicon nitride so that active areas are exposed. Metal is then deposited 116 to fill contact holes and thereby form contact plugs.

### CONCLUSION

Although the various aspects have been described with respect to examples, it will be understood that protection within the full scope of the appended claims is appropriate.

1. A NAND flash memory comprising:
a plurality of active areas in a semiconductor substrate;
a plurality of shallow trench isolation structures in the semiconductor substrate between the plurality of active areas;
a first dielectric layer formed of a first material extending over and lying in contact with the substrate;
a plurality of portions of a second material extending over the first dielectric layer at locations over the plurality of shallow trench isolation structures;
a second dielectric layer formed of the first material extending over the first dielectric layer and over the plurality of portions, the second dielectric layer lying in contact with the plurality of portions; and
a plurality of contact holes extending through the first and second dielectric layers at locations over the plurality of active areas in the semiconductor substrate.

2. The NAND flash memory of claim 1 wherein an individual contact hole is constrained by a portion of the second material where the contact hole extends in a direction that is not perpendicular to a primary surface of the semiconductor substrate, or where the contact hole is misaligned with a corresponding active area.

3. The NAND flash memory of claim 1 further comprising a plurality of metal contacts formed in the plurality of contact holes.

4. The NAND flash memory of claim 3 wherein the plurality of metal contacts form electrical connections with bit lines that extend over the semiconductor substrate.

5. The NAND flash memory of claim 1 wherein the plurality of shallow trench isolation structures have upper surfaces that are lower than upper surfaces of the plurality of active areas with trenches over shallow trench isolation structures lined by the first dielectric layer and the plurality of portions of the second material filling central portions of the trenches.

6. The NAND flash memory of claim 5 wherein the plurality of portions of the second material have upper surfaces that are higher than the upper surfaces of the plurality of active areas and have lower surfaces that are lower than the upper surfaces of the plurality of active areas.

7. The NAND flash memory of claim 1 wherein the plurality of shallow trench isolation structures have upper surfaces that are approximately level with upper surfaces of the plurality of active areas and wherein the plurality of portions of the second material have lower surfaces that are substantially level with the upper surfaces of the plurality of shallow trench isolation structures and the plurality of active areas.

8. The NAND flash memory of claim 7 wherein the plurality of portions of the second material are located over peripheral areas of shallow trench isolation structures.

9. The NAND flash memory of claim 8 wherein the plurality of portions of the second material extend partially over boundaries between shallow trench isolation structures and active areas to overlie peripheral areas of active areas.

10. The NAND flash memory of claim 7 wherein the plurality of portions of the second material extend in a vertical direction and are connected to a layer of the second material.

11. The NAND flash memory of claim 1 wherein the first material is silicon oxide, and the second material is silicon nitride.

12. The NAND flash memory of claim 1 wherein an individual active area has a lateral dimension of less than thirty nanometers (30 nm) and the contact holes have a vertical dimension of greater than four hundred nanometers (400 nm).

13. A method of forming contact holes through a dielectric layer comprising:
forming alternating active areas and shallow trench isolation structures in a substrate, the shallow trench isolation structures having upper surfaces that are lower than upper surfaces of the active areas;
depositing a first dielectric layer over the substrate, the first dielectric layer formed of a first dielectric material;
subsequently depositing a second dielectric material over the first dielectric layer;
subsequently removing excess second dielectric material to leave portions of the second dielectric material over the shallow trench isolation structures;
subsequently depositing a second dielectric layer, the second dielectric layer formed of the first dielectric material;
subsequently forming an etch mask to define contact hole openings in the first dielectric material at locations over active areas; and
subsequently etching a plurality of contact holes in the first and second dielectric layers, the plurality of contact holes etched by a process that etches the first dielectric material at a first etch rate and etches the second dielectric material at a second etch rate, the first etch rate being significantly higher than the second etch rate.

14. The method of claim 13 wherein forming the alternating active areas and shallow trench isolation structures includes lowering the upper surfaces of the shallow trench isolation structures by etching.

15. The method of claim 13 wherein the first material is silicon oxide, the second material is silicon nitride, and the etching is anisotropic etching with a high silicon oxide etch rate.

16. The method of claim 15 wherein the removing includes planarizing to remove all of the second dielectric material that is not within trenches formed between active areas lined by the first dielectric layer.

17. The method of claim 13 further comprising: forming one or more additional dielectric layers over the second dielectric layer, the etch mask subsequently formed over the one or more additional dielectric layers, and the plurality of contact holes etched through the one or more additional dielectric layers.

18. A method of forming contact holes through a dielectric layer comprising:
forming alternating active areas and shallow trench isolation structures in a substrate;
depositing a first dielectric layer over the substrate, the first dielectric layer formed of a first dielectric material;
subsequently forming a plurality of openings through the first dielectric layer over the active areas thereby exposing the active areas;
subsequently depositing a second dielectric material over the first dielectric layer and within the openings;
subsequently depositing a second dielectric layer, the second dielectric layer formed of the first dielectric material;
subsequently forming an etch mask to define contact hole openings in the second dielectric layer at locations over active areas; and
subsequently etching a plurality of contact holes in the first and second dielectric layers, the plurality of contact holes etched by a process that etches the first dielectric material at a first etch rate and etches the second dielectric material at a second etch rate, the first etch rate being significantly higher than the second etch rate.

19. The method of claim 18 wherein upper surfaces of active areas and shallow trench isolation structures are coplanar, the first dielectric layer is substantially planar, and the second dielectric is deposited along inner walls of the openings and along an upper surface of the first dielectric layer.

20. The method of claim 19 further comprising: removing the second dielectric along the upper surface of the first dielectric layer and along the active area prior to deposition of the second dielectric layer.

21. The method of claim 18 wherein the second dielectric material forms an etch-stop layer, and wherein the etching includes a first etch stage that etches through the first material and a second etch stage that etches through the second dielectric material to expose the active area.
